(19) United States
(12) Patent Application Publication
(10) Pub. No.: US 2018/0342461 A1
(43) Pub. Date: Nov. 29, 2018

(54) SENSING SYSTEM

(71) Applicant: Industrial Technology Research Institute, Hsinchu (TW)

(72) Inventors: Chun-Ting Liu, Hsinchu County (TW); Shih-Ming Lin, Chiayi County (TW); Je-Ping Hu, Hsinchu City (TW); Jung-Shiuan Liou, Taoyuan City (TW)

(73) Assignee: Industrial Technology Research Institute, Hsinchu (TW)

(21) Appl. No.: 15/705,277

(22) Filed: Sep. 15, 2017

(30) Foreign Application Priority Data
May 23, 2017 (TW) 106116954

(51) Int. Cl. H01L 23/538; H01L 23/15; H01L 21/48; H01L 25/18; H01L 23/66

(52) U.S. Cl. CPC H01L 23/5384; H01L 23/15; H01L 23/5386; H01L 2223/6616; H01L 21/486; H01L 25/18; H01L 23/66; H01L 21/4803

(57) ABSTRACT

A sensing system including a substrate, at least one explicit device, at least one inner operation device, a plurality of conductors, and a plurality of conductive traces is provided. The substrate has a first surface and a second surface opposite to the first surface, and has a plurality of vias communicating the first surface and the second surface. The explicit device is disposed on the first surface. The explicit device includes a display, a sensor, or a combination thereof. The inner operation device is totally disposed on the second surface. The inner operation device includes a signal processor, a driver, or a combination thereof. The conductors are disposed in the vias, respectively, and connect the at least one explicit device with the at least one inner operation device. The conductive traces are disposed on at least one of the first surface and the second surface.

### CROSS-REFERENCE TO RELATED APPLICATION

This application claims the priority benefit of Taiwan application serial no. 106116954, filed on May 23, 2017. The entirety of the above-mentioned patent application is hereby incorporated by reference herein and made a part of this specification.

### TECHNICAL FIELD

The technical field relates to a sensing system.

### BACKGROUND

Along with progress of electronic component technology, besides various electronic products (for example, portable electronic products) meeting the needs of human life can be implemented, in collaboration with sensors or sensing systems, the electronic products may implement more functions and applications.

The present electronic products are developed towards a trend of lightness, slimness, shortness and smallness, accordingly, the sensors or sensing systems are also developed towards miniaturization, and it is expected that the sensors or sensing systems with a smaller volume may achieve the same or similar functions and effects as that of large sensing systems. Therefore, how to make an effective use of an area on the sensing system becomes an important research and development issue of the field.

Moreover, along with development of semiconductor technology, a computation function and a speed of the electronic components become stronger, and signal frequency thereof is also developed to a high frequency. Therefore, in the sensing system, how to improve a transmission speed of the electronic signals and how to keep integrity and decrease distortion of the electronic signals become an important issue for related designers of the present sensing system.

### SUMMARY

An embodiment of the disclosure provides a sensing system including a substrate, at least one explicit device, at least one inner operation device, a plurality of conductors, and a plurality of conductive traces. The substrate has a first surface and a second surface opposite to the first surface, and has a plurality of vias communicating the first surface and the second surface. The explicit device is disposed on the first surface, where the at least one explicit device includes a display, a sensor, or a combination thereof. The inner operation device is totally disposed on the second surface, where the at least one inner operation device includes a signal processor, a driver, or a combination thereof. The conductors are respectively disposed in the vias, and connect the at least one explicit device with the at least one inner operation device. The conductive traces are disposed on at least one of the first surface and the second surface. A depth-to-width ratio obtained by dividing a depth of each via in a direction perpendicular to the first surface by a width thereof in a direction parallel to the first surface is greater than or equal to 1.5, and a thickness-to-width ratio obtained by dividing a thickness of each conductive trace in the direction perpendicular to the first surface by a width thereof in a direction parallel to the first surface is greater than or equal to 1.5.

An embodiment of the disclosure provides a sensing system including a substrate, at least one explicit device, at least one inner operation device, at least one physiological sensing device, a plurality of conductors, and a plurality of conductive traces. The substrate has a first surface and a second surface opposite to the first surface, and has a plurality of vias communicating the first surface and the second surface. The explicit device is disposed on the first surface, where the at least one explicit device includes a display, a sensor, or a combination thereof. The inner operation device is totally disposed on the second surface, where the at least one inner operation device includes a signal processor, a driver, or a combination thereof. The conductors are respectively disposed in the vias, and connect the at least one explicit device with the at least one inner operation device or the at least one physiological sensing device. The conductive traces are disposed on at least one of the first surface and the second surface. A depth-to-width ratio obtained by dividing a depth of each via in a direction perpendicular to the first surface by a width thereof in a direction parallel to the first surface is greater than or equal to 1.5, and a thickness-to-width ratio obtained by dividing a thickness of each conductive trace in the direction perpendicular to the first surface by a width thereof in a direction parallel to the first surface is greater than or equal to 1.5.

An embodiment of the disclosure provides a sensing system including a substrate, at least one explicit device, at least one inner operation device, a plurality of conductors, and a plurality of conductive traces. The substrate has a first surface and a second surface opposite to the first surface, and has a plurality of vias communicating the first surface and the second surface. The explicit device is disposed on the first surface, where the at least one explicit device includes a display, a sensor, or a combination thereof. The inner operation device is totally disposed on the second surface, where the at least one inner operation device includes a signal processor, a driver, or a combination thereof. The conductors are respectively disposed in the vias, and directly connected to the at least one explicit device and the at least one inner operation device. The conductive traces are disposed on at least one of the first surface and the second surface.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1A is a perspective view of a front side of a sensing system according to an embodiment of the disclosure.

FIG. 1B is a perspective view of a back side of the sensing system according to an embodiment of the disclosure.

FIG. 1C is a cross-sectional view of the sensing system of FIG. 1A and FIG. 1B along a line I-I.

FIG. 2A is a partial cross-sectional view of a sensing system according to an embodiment of the disclosure.

FIG. 2B is an enlarged view of a region A1 in FIG. 2A.

FIG. 2C is an enlarged view of a region A2 in FIG. 2A.

FIG. 3 is a cross-sectional view showing a process of forming conductive traces on a substrate.

FIG. 4 is a cross-sectional view of a sensing system according to another embodiment of the disclosure.

### DESCRIPTION OF EMBODIMENTS

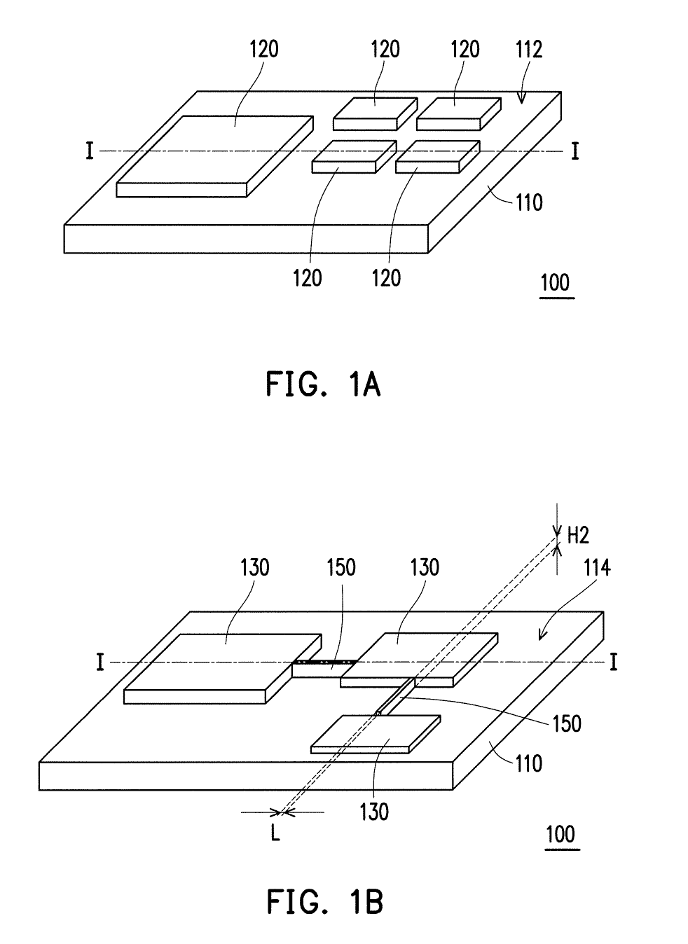

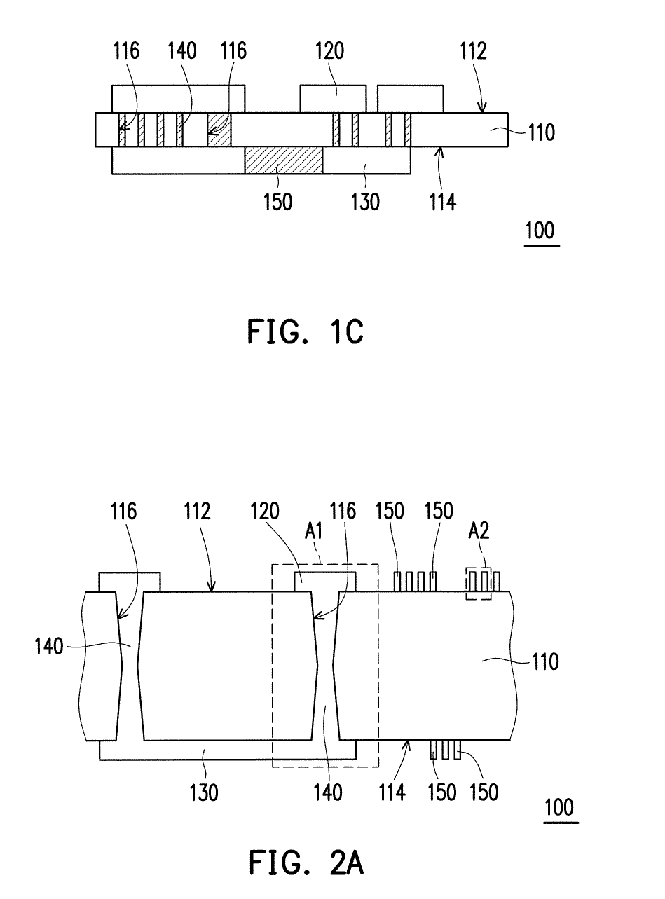

FIG. 1A is a perspective view of a front side of a sensing system according to an embodiment of the disclosure, FIG. 1B is a perspective view of a back side of the sensing system according to an embodiment of the disclosure, and FIG. 1C is a cross-sectional view of the sensing system of FIG. 1A and FIG. 1B along a line I-I. FIG. 2A is a partial cross-sectional view of a sensing system according to an embodiment of the disclosure, FIG. 2B is an enlarged view of a region A1 in FIG. 2A, and FIG. 2C is an enlarged view of a region A2 in FIG. 2A. Referring to FIG. 1A to FIG. 2C, the sensing system 100 of the present embodiment includes a substrate 110, at least one explicit device 120 (a plurality of explicit devices 120 is illustrated for example), at least one inner operation device 130 ((a plurality of inner operation devices 130 is illustrated for example), a plurality of conductors 140, and a plurality of conductive traces 150. The substrate 110 has a first surface 112 and a second surface 114 opposite to the first surface 112, and has a plurality of vias 116 communicating the first surface 112 and the second surface 114. The explicit devices 120 are disposed on the first surface 112. The at least one explicit device 120 includes a display, a sensor, or a combination thereof. In an embodiment, the at least one explicit device 120 includes a sensor, and the sensor includes an environment temperature sensor, an environment humidity sensor, an environment microparticle sensor (e.g. a PM2.5 sensor), an environment ultraviolet sensor, an environment radiation sensor, other types of sensors or a combination thereof.

The inner operation devices 130 are totally disposed on the second surface 114, where the at least one inner operation device 130 includes a signal processor, a driver, or a combination thereof. In an embodiment, the at least one inner operation device 130 further includes an analog-to-digital converter, a passive device, a memory, a power supply or a combination thereof. The conductors 140 are respectively disposed in the vias 116, and connect the at least one explicit device 120 with the at least one inner operation device 130. The conductive traces 150 are disposed on at least one of the first surface 112 and the second surface 114. For example, in FIG. 1B, the conductive traces 150 are disposed on the second surface 114. However, in FIG. 2A, the conductive traces 150 are disposed on the first surface 112 and the second surface 114.

In the present embodiment, a depth-to-width ratio obtained by dividing a depth H1 of each via 116 in a direction perpendicular to the first surface 112 by a width D (for example, the minimum diameter) thereof in a direction parallel to the first surface 112 is greater than or equal to 1.5 (shown in FIG. 2B), and a thickness-to-width ratio obtained by dividing a thickness H2 of each conductive trace 150 in the direction perpendicular to the first surface 112 by a width L thereof in a direction parallel to the first surface 112 is greater than or equal to 1.5. Moreover, in the present embodiment, a material of the substrate 110 is a silicon-oxide-based material, for example, quartz or glass, i.e. the substrate 110 is, for example, a glass substrate or a quartz substrate. In other embodiments, a material of the substrate 110 may be a silicon-nitride-based material. In this way, a dielectric constant Dk of the sensing system 100 is smaller than 6.0 and a dielectric loss tangent Df thereof is smaller than 0.01 when a signal (electric signal) frequency thereof is greater than 10 GHz. When the dielectric constant Dk is small, the signal (electric signal) has a high transmission rate, and when the dielectric loss tangent Df is small, signal (electric signal) integrity is kept to decrease a signal distortion. Therefore, the sensing system of the present embodiment may have a good performance in high frequency applications. In the present embodiment, a visible light transmittance of the substrate 110 may be greater than 80%. In other words, the substrate 110 may be a transparent substrate. Moreover, the substrate 110 made of the silicon-oxide-based material has better ability of anti-moisture and high thermal stability compared to a plastic substrate, and has smaller dielectric loss tangent Df.

In the present embodiment, a root mean square roughness R_{RMS} of wall surfaces of the vias 116 is smaller than 100 nm, and a root mean square roughness R_{RMS} of surfaces of the conductive traces 150 is smaller than 100 nm, which avails decreasing the dielectric constant Dk and the dielectric loss tangent Df under the high frequency applications. The more smooth the surfaces of the conductive trace 150 are, the less the signal transmission loss under the high frequency applications is. Moreover, in the present embodiment, the width D (for example, the minimum diameter) of each via 116 is smaller than or equal to 10 μm, and an included angle θ between the wall surface of each via 116 and a central axis C of the each via 116 along an extending direction thereof is smaller than or equal to 5 degrees, which avails decreasing the dielectric constant Dk and the dielectric loss tangent Df under the high frequency applications. The smaller the width D is and the smaller the included angle θ is, the less the signal transmission loss under the high frequency application greater than 20 GHz is. Moreover, the width L of each conductive trace 150 may be controlled to be smaller than or equal to 5 μm.

In the present embodiment, since the conductors 140 are directly connected to the at least one explicit device 120 and the at least one inner operation device 130, and the inner operation devices 130 are totally disposed on the second surface 114, a usable area of the explicit device 120 may be effectively increased, for example, an area of a display or a sensor may be enlarged. Moreover, since the conductors 140 are disposed in the vias 116, a signal-to-noise ratio of the sensing system 100 may be effectively increased. In the present embodiment, a material of the conductors 140 is metal, for example, copper or other materials with good conductivity.

In an embodiment, in order to make the root mean square roughness R_{RMS} of the wall surfaces of the vias 116 to be complied with the aforementioned specification, a laser ablation process may be adopted to ablate the vias 116 on the substrate 110, or a laser damage process and a wet etching process may be adopted to form the vias 116 on the substrate 110.

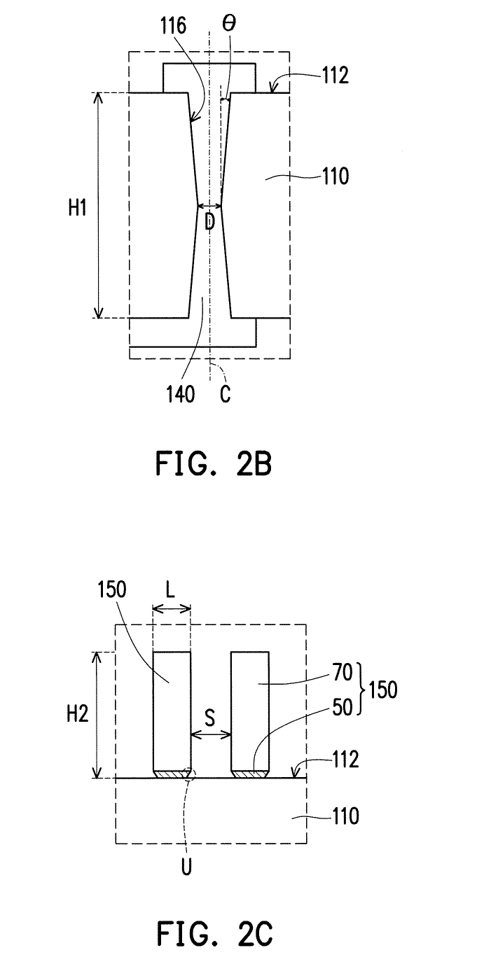

FIG. 3 is a cross-sectional view showing a process of forming the conductive traces on the substrate. Referring to FIG. 3, in order to make the root mean square roughness R_{RMS} of the surfaces of the conductive traces 150 to be complied with the aforementioned specification, a following process may be adopted to form the conductive traces 150. First, a seed layer 50 is formed on the substrate 110, where the seed layer 50 may be a nickel seed layer, for example, a chemical black nickel layer.

Then, a patterned photoresist layer 60 is formed on the seed layer 50, and a method of forming the patterned photoresist layer 60 may be to first form a photoresist layer on the seed layer 50 to cover the entire surface, and then perform a partial exposure (i.e. patterned exposure) and development process to the photoresist layer to form the patterned photoresist layer 60. The chemical black nickel layer may serve as an anti-reflection layer to decrease generation of reflected light during the exposure process, so as to effectively decrease a phenomenon that the reflected light is interfered with an incident light to produce standing wave lines on a sidewall of the subsequently formed patterned photoresist layer 60, where the standing wave lines may cause unsmoothness of the surface of the conductive traces 150 to increase the root mean square roughness R_{RMS} thereof. The above exposure process may adopt laser direct imaging (LDI) exposure. Moreover, in the present embodiment, a postdevelopment bake technique may be adopted to process the developed patterned photoresist layer 60. The postdevelopment bake technique makes the photoresist to produce partial mobility to eliminate the standing wave lines on the sidewall of the patterned photoresist layer 60. Then, a conductive layer 70 is formed on a part of the seed layer 50 that is not covered by the patterned photoresist layer 60 through an electroplating process, where a material of the conductive layer is, for example, copper or other metal with good conductivity.

Then, the patterned photoresist layer 60 is removed. Then, the seed layer 50 that is not covered by the conductive layer 70 is etched. Then, an electropolishing process is performed and a repair coating layer (which may be an electroplating layer or a non-electroplating layer) is formed after polishing, so as to further repair a rough conductor surface caused by the lithography etching process to improve transmission quality of the high frequency signal. In this way, the remained seed layer 50 and the conductive layer 70 form the conductive traces 150. Based on the aforementioned process, the conductive traces 150 with a smooth surface may be forming.

Referring to FIG. 2B and FIG. 2C, in an embodiment, the width D (for example, the minimum diameter) of each via 116 is, for example, 5 μm, the depth H1 of each via 116 is, for example, 50 μm, and the included angle θ between the wall surface of each via 116 and the central axis C of the each via 116 along the extending direction thereof is smaller than or equal to 5 degrees. Moreover, in case that the width L (i.e. a line width) of each conductive trace 150 in the direction parallel to the first surface 112 is, for example, 2 μm, the thickness H2 of each conductive trace 150 in the direction perpendicular to the first surface 112 is, for example, 6 μm, a space S between two adjacent conductive traces 150 is, for example, 2 μm, an undercut U of the seed layer 50 is smaller than or equal to 10%, and a signal frequency of the sensing system 100 is greater than 20 GHz, the root mean square roughness R_{RmS} of the surfaces of the conductive traces 150 is smaller than 100 nm. In another embodiment, the width L may be 5 μm and the thickness H2 may be 7.5 μm, such that the thickness-to-width ratio (a ratio obtained by dividing the thickness H2 by the width L) of the conductive traces 150 may be 1.5.

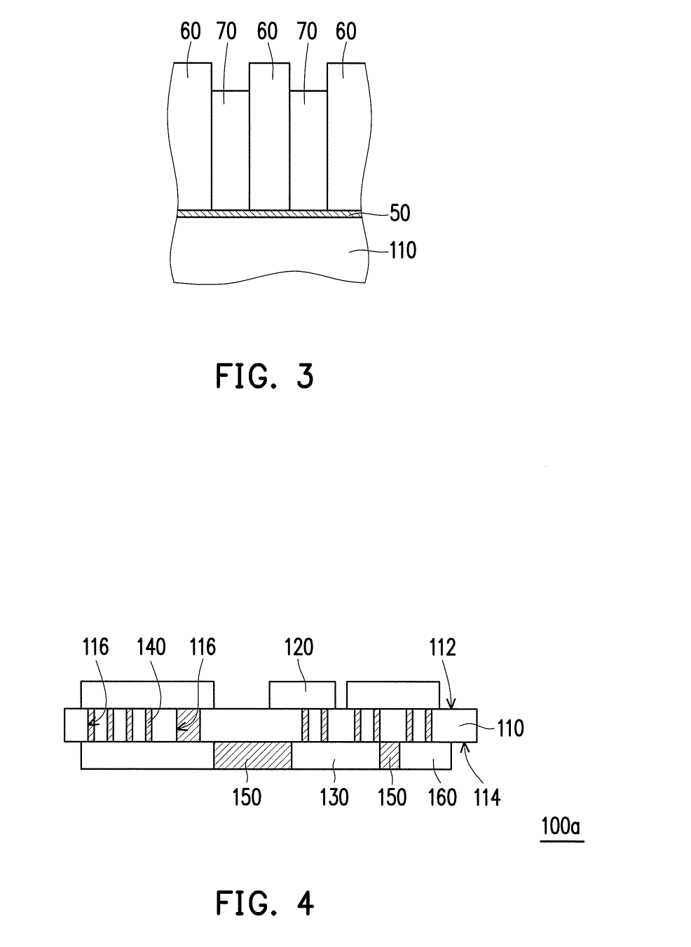

FIG. 4 is a cross-sectional view of a sensing system according to another embodiment of the disclosure. Referring to FIG. 4, the sensing system 100a of the present embodiment is similar to the sensing system 100 of FIG. 1C, and main differences therebetween are that the sensing system 100a of the present embodiment further includes at least one physiological sensing device 160 (one physiological sensing device is illustrated in FIG. 4 for example), and the conductors 140 connects the explicit devices 120 with the inner operation device 130 or the physiological sensing device 160. In the present embodiment, a part of the conductors 140 connects the explicit device 120 with the inner operation device 130, and another part of the conductors 140 connects the explicit device 120 with the physiological sensing device 160. Moreover, in the present embodiment, the physiological sensing device 160 is disposed on the second surface 114. However, in other embodiment, the physiological sensing device 160 may be disposed on the first surface 112. Moreover, in the present embodiment, the physiological sensing device 160 may be used for sensing a pulse, a blood pressure, a skin resistance, a body fluid composition or a combination thereof. Moreover, in the present embodiment, the physiological sensing device 160 may be electrically connected to the inner operation devices 130 through the conductive traces 150.

In summary, in the sensing system of the embodiments of the disclosure, since the depth-to-width ratio obtained by dividing the depth of each via in the direction perpendicular to the first surface by the width thereof in the direction parallel to the first surface is greater than or equal to 1.5, and the thickness-to-width ratio obtained by dividing the thickness of each conductive trace in the direction perpendicular to the first surface by the width thereof in the direction parallel to the first surface is greater than or equal to 1.5, the sensing system may have good performance under the high frequency applications. Moreover, in the sensing system of the embodiments of the disclosure, since the conductors are respectively disposed in the vias, and directly connected to the at least one explicit device and the at least one inner operation device, and the inner operation devices are all disposed on the second surface, the area on the sensing system can be effectively used, and the signal-to-noise ratio of signals may be effectively increased.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A sensing system, comprising:
a substrate, having a first surface and a second surface opposite to the first surface, and having a plurality of vias communicating the first surface and the second surface;
at least one explicit device, disposed on the first surface, wherein the at least one explicit device comprises a display, a sensor, or a combination thereof;
at least one inner operation device, totally disposed on the second surface, wherein the at least one inner operation device comprises a signal processor, a driver, or a combination thereof;
a plurality of conductors, respectively disposed in the vias, and connecting the at least one explicit device with the at least one inner operation device; and
a plurality of conductive traces, disposed on at least one of the first surface and the second surface,
wherein a depth-to-width ratio obtained by dividing a depth of each via in a direction perpendicular to the first surface by a width thereof in a direction parallel to the first surface is greater than or equal to 1.5, and a thickness-to-width ratio obtained by dividing a thickness of each conductive trace in the direction perpendicular to the first surface by a width thereof in a direction parallel to the first surface is greater than or equal to 1.5.

2. The sensing system as claimed in claim 1, wherein a dielectric constant of the sensing system is smaller than 6.0 and a dielectric loss tangent thereof is smaller than 0.01 when a signal frequency thereof is greater than 10 GHz.

3. The sensing system as claimed in claim 1, wherein a root mean square roughness R_{RMS} of wall surfaces of the vias is smaller than 100 nm.

4. The sensing system as claimed in claim 1, wherein a root mean square roughness R_{RMS} of surfaces of the conductive traces is smaller than 100 nm.

5. The sensing system as claimed in claim 1, wherein a diameter of each of the vias is smaller than or equal to 10 μm.

6. The sensing system as claimed in claim 1, wherein an included angle between a wall surface of each via and a central axis of the each via along an extending direction thereof is smaller than or equal to 5 degrees.

7. The sensing system as claimed in claim 1, wherein a visible light transmittance of the substrate is greater than 80%.

8. The sensing system as claimed in claim 1, wherein a material of the substrate is a silicon-oxide-based material or a silicon-nitride-based material.

9. The sensing system as claimed in claim 1, wherein the at least one explicit device comprises the sensor, and the sensor comprises an environment temperature sensor, an environment humidity sensor, an environment microparticle sensor, an environment ultraviolet sensor, an environment radiation sensor, or a combination thereof.

10. The sensing system as claimed in claim 1, wherein the at least one inner operation device further comprises an analog-to-digital converter, a passive device, a memory, a power supply or a combination thereof.

11. The sensing system as claimed in claim 1, wherein the conductors is directly connected to the at least one explicit device and the at least one inner operation device.

12. A sensing system, comprising:
a substrate, having a first surface and a second surface opposite to the first surface, and having a plurality of vias communicating the first surface and the second surface;
at least one explicit device, disposed on the first surface, wherein the at least one explicit device comprises a display, a sensor, or a combination thereof;
at least one inner operation device, totally disposed on the second surface, wherein the at least one inner operation device comprises a signal processor, a driver, or a combination thereof;
a plurality of conductors, respectively disposed in the vias, and directly connected to the at least one explicit device and the at least one inner operation device; and
a plurality of conductive traces, disposed on at least one of the first surface and the second surface.

13. The sensing system as claimed in claim 12, wherein a dielectric constant of the sensing system is smaller than 6.0 and a dielectric loss tangent thereof is smaller than 0.01 when a signal frequency thereof is greater than 10 GHz.

14. The sensing system as claimed in claim 12, wherein a root mean square roughness R_{RMS} of wall surfaces of the vias is smaller than 100 nm.

15. The sensing system as claimed in claim 12, wherein a root mean square roughness R_{RMS} of surfaces of the conductive traces is smaller than 100 nm.

16. The sensing system as claimed in claim 12, wherein a diameter of each of the vias is smaller than or equal to 10 μm.

17. The sensing system as claimed in claim 12, wherein an included angle between a wall surface of each via and a central axis of the each via along an extending direction thereof is smaller than or equal to 5 degrees.

18. The sensing system as claimed in claim 12, wherein a visible light transmittance of the substrate is greater than 80%.

19. The sensing system as claimed in claim 12, wherein a material of the substrate is a silicon-oxide-based material or a silicon-nitride-based material.

20. The sensing system as claimed in claim 19, wherein the substrate is a glass substrate or a quartz substrate.

21. The sensing system as claimed in claim 12, wherein the at least one explicit device comprises the sensor, and the sensor comprises an environment temperature sensor, an environment humidity sensor, an environment microparticle sensor, an environment ultraviolet sensor, an environment radiation sensor, or a combination thereof.

22. The sensing system as claimed in claim 12, wherein the at least one inner operation device further comprises an analog-to-digital converter, a passive device, a memory, a power supply or a combination thereof.

23. A sensing system, comprising:
a substrate, having a first surface and a second surface opposite to the first surface, and having a plurality of vias communicating the first surface and the second surface;
at least one explicit device, disposed on the first surface, wherein the at least one explicit device comprises a display, a sensor, or a combination thereof;
at least one inner operation device, totally disposed on the second surface, wherein the at least one inner operation device comprises a signal processor, a driver, or a combination thereof;
at least one physiological sensing device;
a plurality of conductors, respectively disposed in the vias, and connecting the at least one explicit device with the at least one inner operation device or the at least one physiological sensing device; and
a plurality of conductive traces, disposed on at least one of the first surface and the second surface,
wherein a depth-to-width ratio obtained by dividing a depth of each via in a direction perpendicular to the first surface by a width thereof in a direction parallel to the first surface is greater than or equal to 1.5, and a thickness-to-width ratio obtained by dividing a thickness of each conductive trace in the direction perpendicular to the first surface by a width thereof in a direction parallel to the first surface is greater than or equal to 1.5.
